(19) United States
(12) Patent Application Publication
(10) Pub. No.: US 2021/0399161 A1
(43) Pub. Date: Dec. 23, 2021

(54) MASS TRANSFER APPARATUS AND MASS TRANSFER METHOD

(71) Applicant: CHONGQING KONKA PHOTOELECTRIC TECHNOLOGY RESEARCH INSTITUTE CO., LTD., Chongqing (CN)

(72) Inventor: Guangping JIANG, Chongqing (CN)

(21) Appl. No.: 17/344,994

(22) Filed: Jun. 11, 2021

Related U.S. Application Data
(63) Continuation of application No. PCT/CN2020/096843, filed on Jun. 18, 2020.

(51) Int. Cl. H01L 33/00; B23K 26/06; H01L 33/58

(52) U.S. Cl. CPC H01L 33/005; B23K 26/0665; H01L 2933/0058; H01L 33/58; B23K 26/0648

(57) ABSTRACT

The application relates to a mass transfer apparatus and a mass transfer method. The apparatus includes: a laser device configured to emit a laser beam; a first lens configured to shape the laser beam into a circular light spot through the first lens; and a second lens configured to guide the circular light spot to a first substrate on which to-be-transferred micro light-emitting diode chips are mounted. A transmission assembly is fixed on the second lens and configured to move the second lens to adjust a distance between the first lens and the second lens so as to adjust a diameter of the circular light spot.

### TECHNICAL FIELD

The application relates to the field of micro light-emitting diode technologies, in particular to a mass transfer apparatus and a mass transfer method.

### BACKGROUND

A Micro Light-Emitting Diode (Micro-LED) has better photoelectric efficiency, brightness and contrast ratio and lower power consumption than a general light-emitting diode. A plurality of Micro-LEDs are mounted on a light-emitting backplane to form a Micro-LED array. After being formed on a growth substrate, the Micro-LED is required to be transferred to a temporary substrate, and then is transferred to the light-emitting backplane from the temporary substrate when it is required to be mounted on the light-emitting backplane. The Micro-LED is fixed on the temporary substrate through a bonding layer, and a process of separating the Micro-LED from the temporary substrate is referred to as lift-off in the industry. Generally, a laser lift-off apparatus is a key device used in a lift-off stage.

At present, laser lift-off of the Micro-LED is generally realized by a galvanometer scanning technology. A galvanometer scanning mode needs to control the position of light spots of a laser beam by controlling reflectors of an X axis and a Y axis (that is, reflection angles of the two reflectors are respectively adjusted by a galvanometer corresponding to the X axis and a galvanometer corresponding to the Y axis, so as to control an angle of an incident beam to the scene to allow the incident beam to reach the position of a focus point on a standard part). The light spots must have overlaps which have a size requirement. In order to meet the size requirement of the overlaps, the size of the light spots generally is required to be controlled within 100 microns. However, controlling the position of the light spots of the laser beam by controlling the reflectors of the X-axis and Y-axis is particularly sensitive to vibrations and stresses of external environments, and accuracy of motors. Therefore, it is difficult to precisely control a light spot trajectory, and a large laser energy deviation between edge overlaps of the light spots may be caused, resulting in that a part of the overlaps have too much laser energy that may burn a separated object, and a part of the overlaps have too small laser energy or there is even no overlap so that the laser energy is too small to separate the object.

Therefore, how to precisely control the light spot trajectory to make the laser scanning energy uniform on the overlaps is an urgent problem to be solved.

### SUMMARY

In view of the above-mentioned defects in the related art, the present application is intended to provide a mass transfer apparatus and a mass transfer method, aiming to solve the problem that a large laser energy deviation between edge overlaps of the light spots may result in that a part of the overlaps have too much laser energy that may burn a separated object, and a part of the overlaps have too small laser energy or there is even no overlap so that the laser energy is too small to separate the object.

A mass transfer apparatus includes a laser device, a first lens, a second lens, and a transmission assembly.

The laser device is configured to emit a laser beam.

The first lens and the second lens are sequentially arranged on an emergent light path of the laser device.

The first lens is configured to shape the laser beam into a circular light spot.

The second lens is configured to guide the circular light spot to a first substrate on which to-be-transferred Micro-LED chips are mounted.

The transmission assembly is fixed on the second lens and the transmission assembly is configured to move the second lens to adjust a distance between the first lens and the second lens so as to adjust a diameter of the circular light spot.

In the foregoing mass transfer apparatus, the circular light spot is formed at the position of the to-be-transferred Micro-LED chips, and the distance between the first lens and the second lens is adjusted through the transmission assembly, so that the diameter of the circular light spot can be adjusted. Thus, a laser scanning mode in the application refers to a mode of scanning in the unit of circles and changing the scanning position by changing diameters of the circles. An overlapping mode of the scanning mode adopted in the application refers to an overlap between one circle and another circle. There is no overlap on the same circle, thereby making the laser energy more uniform. The overlap between the circles may be controlled by only controlling the distance between the first lens and the second lens, thereby precisely controlling a light spot trajectory to make the laser scanning energy on the overlap uniform. Therefore, according to the application, the laser scanning energy received on the entire wafer can be uniform, avoiding the problem that a large laser energy deviation between edge overlaps of the light spots may result in that a part of the overlaps have too much laser energy that may burn a separated object, and a part of the overlaps have too small laser energy or there is even no overlap so that the laser energy is too small to separate the object.

Optionally, the circular light spot is shaped as a circle, and the diameter of the circular light spot is linearly increased or decreased along with changes of the distance between the first lens and the second lens. When the transmission assembly drives the second lens to move in a direction away from the first lens, the distance between the first lens and the second lens is increased, so that the diameter of the circular light spot formed on the first substrate by the laser beam transmitted through the first lens and the second lens from the laser device is larger. Similarly, if the transmission assembly drives the second lens to move in a direction close to the first lens, the distance between the first lens and the second lens is decreased, so that the diameter of the circular light spot formed on the first substrate by the laser beam transmitted through the first lens and the second lens from the laser device is smaller.

Optionally, the distance between the first lens and the second lens is less than or equal to a focal length of the first lens.

Optionally, the laser device, the first lens, and the second lens are coaxially arranged.

Optionally, the first lens is an annular focusing lens, the annular focusing lens includes a focusing lens and a first conical lens, the first conical lens has a first cone angle, and the laser beam is transmitted to the second lens through the focusing lens and the first conical lens.

Optionally, the second lens is a second conical lens, the second conical lens has a second cone angle, and the laser beam is transmitted through the second conical lens to form the circular light spot at the position of the to-be-transferred Micro-LED chips.

Optionally, the first cone angle is equal to the second cone angle.

Optionally, the first cone angle and the second cone angle both range from 45 degrees to 90 degrees.

Optionally, the mass transfer apparatus further includes a collimating lens, the collimating lens is arranged on the laser path of the laser device, and the collimating lens is configured to form a divergent beam emitted from the laser device into a collimated beam and transmit the collimated beam to the first lens. The collimated beam is formed by the divergent beam emitted from the laser and is transmitted to the first lens.

Optionally, the transmission assembly includes a drive motor, a screw disposed on the drive motor, and a clamp disposed on the screw; the clamp is connected to the second lens; and during running of the drive motor, the second lens moves front and back along a parallel direction of the screw through the clamp. During running of the drive motor, the drive motor drives the screw to rotate, the screw drives the clamp to move front and back on the screw, so as to drive the second lens to move front and back along the parallel direction of the screw along with the clamp, thereby achieving the purpose of adjusting the distance between the second lens and the first lens, and further achieving the purpose of changing the diameter of the circular light spot by controlling the distance between the first lens and the second lens.

Optionally, the mass transfer apparatus further includes a controller, the controller is respectively electrically connected to the laser and the drive motor. In a transfer process of the to-be-transferred Micro-LED chips, the controller sends a scanning signal, and the drive motor receives the scanning signal and drives the second lens to move front and back along the parallel direction of the screw, so as to adjust the diameter of the circular light spot. Moreover, the controller generates a laser pulse signal to the laser device while generating the scanning signal. When a laser trajectory (a movement trajectory of the circular light spot) moves to the position of the to-be-transferred Micro-LED chips, the laser device is triggered to be lighted, so that the to-be-transferred Micro-LED chips corresponding to the circular light spot are separated from the first substrate.

Based on the same inventive concept, the present application further provides a mass transfer method, including the following operations.

After the transmission assembly receives a scanning signal, the drive motor is adjusted to rotate according to the scanning signal to control movement of the second lens to adjust a distance between the first lens and the second lens so as to adjust a diameter of the circular light spot.

After the laser device receives a laser pulse signal, on and off of laser is adjusted according to the laser pulse signal.

The laser pulse signal corresponds to the scanning signal; when a laser beam trajectory moves to the position of the to-be-transferred Micro-LED chips, the laser device is turned on to separate the to-be-transferred Micro-LED chips from the first substrate; and when the laser beam trajectory moves to the position out of the to-be-transferred Micro-LED chips, the laser device is turned off.

With the foregoing mass transfer method, when the transmission assembly receives the scanning signal, the diameter of the circular light spot is adjusted as needed by controlling the distance between the first lens and the second lens; when the laser beam trajectory moves to the position of the to-be-transferred Micro-LED chips, the laser device is turned on to separate the to-be-transferred Micro-LED chips from the first substrate.

### BRIEF DESCRIPTION OF THE DRAWINGS

FIG. 1 is a schematic structural diagram of a mass transfer apparatus in the application.

FIG. 2 is a schematic diagram of a transfer process of to-be-transferred Micro-LED chips.

FIG. 3 is a schematic diagram of overlaps between light spots when a laser beam is focused to a point.

FIG. 4 is a schematic diagram of overlaps between light spots when a laser beam is focused to a circle.

FIG. 5 is a schematic structural diagram of a first lens.

FIG. 6 is a schematic flowchart of a mass transfer method in the application.

### Reference Signs

1, laser device; 2, collimating lens; 3, first lens; 4, second lens; 5, transmission assembly; 51, drive motor; 52, screw; 53, clamp; 6, first substrate; 61, release layer; 7, second substrate; 71, bonding layer; 8, to-be-transferred Micro-LED chip; 9, circular light spot; and 10, overlap.

### DETAILED DESCRIPTION OF THE EMBODIMENTS

To facilitate understanding the present application, the present application will be described more comprehensively below with reference to the related drawings. Preferred implementations of the present application are provided in the drawings. The present application may be implemented in different manners and is not limited to the implementations described herein. On the contrary, these implementations are provided to intend to make the understanding of the application of the present application more thorough and comprehensive.

Unless otherwise defined, all technical and scientific terms used herein have the same meaning as commonly understood by those skilled in the art of the present application. The terms used in the specification of the present application herein are only for the purpose of describing the specific implementations, and not intended to limit the present application.

At present, laser processing basically refers to focusing a laser beam to a point and scanning in the unit of points. The purpose of scanning is achieved by changing the position of the focus point. Specifically, reflection angles of an X scanning mirror and a Y scanning mirror are respectively controlled by a galvanometer X and a galvanometer Y, so that the angle of an incident laser beam to a field lens is controlled. The application changes the traditional thinking, takes circles as the unit, and achieves scanning by changing sizes of the circles. For example, a target scan may be a round wafer in a size such as 2 inches or 8 inches. Because the laser lift-off device requires that the entire wafer must be scanned during the lift-off and the laser energy scanned at each position is the same, and laser is in Gaussian distribution, in a conventional scanning method with points as the unit, a fixed-sized overlap between one point and another point is inevitable, which will increase the difficulty of scanning. However, during scanning in the unit of circles, only the control on an overlap between one circle and another circle is needed, which is easier than the control on an overlap between one point and another point, so that the laser energy is more uniform in scanning.

Based on this, the present application is intended to provide a solution that can solve the above-mentioned technical problems, the details of which will be described in subsequent embodiments.

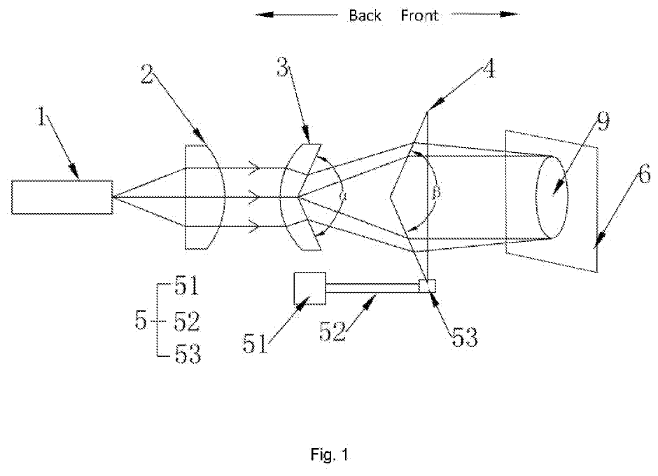

As shown in FIG. 1 to FIG. 5, the application provides the embodiments of a mass transfer apparatus.

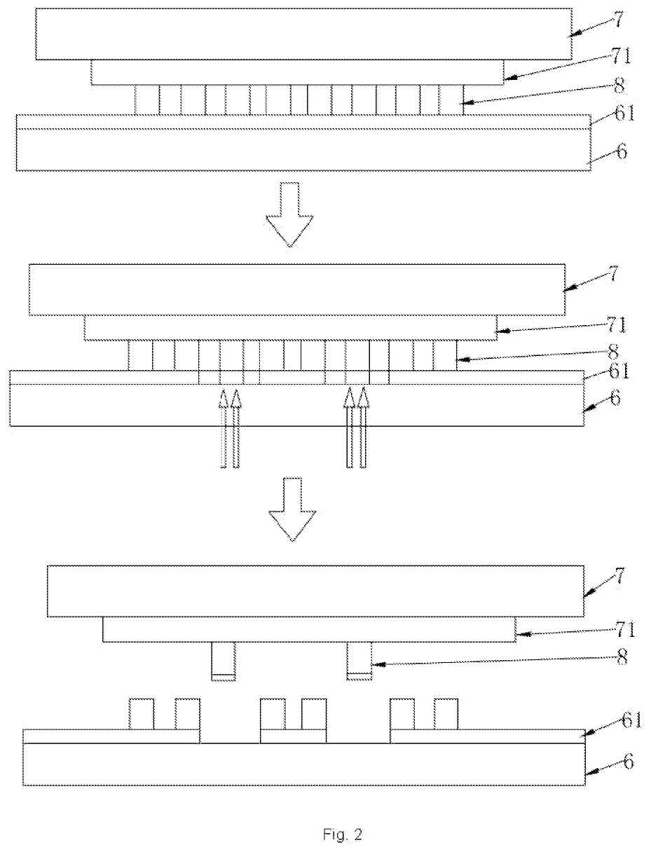

Referring to FIG. 1 and FIG. 2, the application provides a mass transfer apparatus for separating to-be-transferred Micro-LED chips 8 from a first substrate 6. The apparatus includes a laser device 1, a first lens 3, a second lens 4, and a transmission assembly 5. Specifically, the laser device 1 can emit a laser beam. The first lens 3 and the second lens 4 are sequentially arranged on an emergent light path of the laser device 1. The first lens 3 is arranged on one side of the laser device 1. The laser beam is transmitted through the first lens 3 to be shaped into a circular light spot 9. The circular light spot 9 can separate the to-be-transferred Micro-LED chips 8 from the first substrate 6. The second lens 4 and the first lens 3 are arranged at an interval and disposed on the side opposite to the to-be-transferred Micro-LED chips 8, can guide the circular light spot to the first substrate 6 on which the to-be-transferred Micro-LED chips are mounted. The transmission assembly 5 is connected to the second lens 4. When the transmission assembly 5 works, the second lens 4 can be moved, so that a distance between the first lens 3 and the second lens 4 can be adjusted, and thus a diameter of the circular light spot 9 can be adjusted.

In the foregoing mass transfer apparatus, since the circular light spot 9 is formed at the position of the to-be-transferred Micro-LED chips 8, the to-be-transferred Micro-LED chips 8 can be separated from the first substrate 6; the distance between the first lens 3 and the second lens 4 is adjusted by the transmission assembly 5, so that the diameter of the circular light spot can be adjusted. Thus, a laser scanning mode in the application refers to a mode of scanning in the unit of circles and changing the scanning position by changing diameters of the circles. An overlapping mode of the scanning mode adopted in the application refers to an overlap between one circle and another circle. There is no overlap 10 on a same circle, thereby making the laser energy more uniform. The overlap 10 between the circles may be controlled by only controlling the distance between the first lens 3 and the second lens 4, thereby precisely controlling the light spot trajectory to make the laser scanning energy on the overlap 10 uniform. Therefore, according to the application, the laser scanning energy received on the entire wafer can be uniform, avoiding the problem that a large laser energy deviation between edge overlaps of the light spots may result in that a part of the overlaps have too much laser energy that may burn a separated object, and a part of the overlaps have too small laser energy or there is even no overlap so that the laser energy is too small to separate the object.

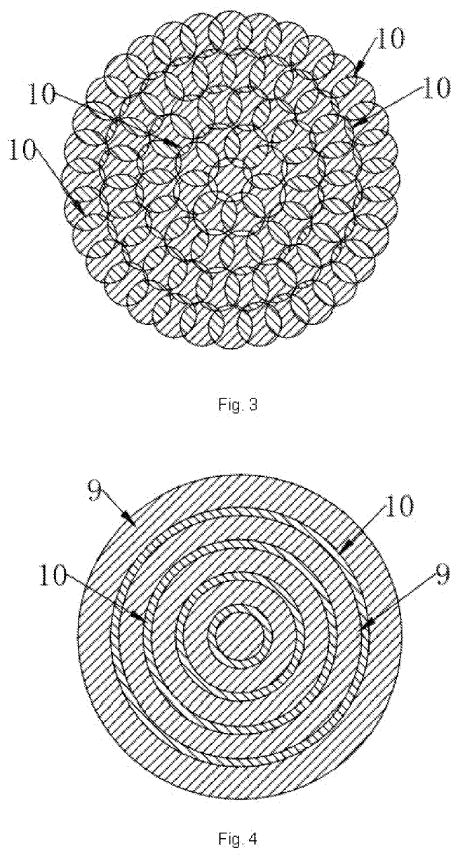

In order to further understand the technical effect brought by the application, referring to FIG. 3 and FIG. 4, FIG. 3 is a schematic diagram of overlaps between light spots when a laser beam is focused to a point, and FIG. 4 is a schematic diagram of overlaps between light spots when a laser beam is focused to a circle. As can be seen from FIG. 3, the scanning mode of focusing the laser beam to a point not only requires a fixed-size overlap 10 between one circle and another circle, but also requires an overlap 10 between one point and another point on the same circle. Sizes of the overlaps 10 between points are required to be the same. If the sizes are inconsistent, a control deviation of one of the points may be larger, a butterfly effect may be caused, so that a part of the overlaps 10 have too much laser energy that may burn a separated object, while a part of the overlaps 10 have too small laser energy or there is even no overlap so the laser energy is too small to separate the object. It can be seen from FIG. 4 that the laser beam adopts the circle-to-circle overlapping mode, which needs overlap areas significantly less than the point-to-point overlapping mode. With the circle-to-circle overlapping mode, there are no overlaps in left and right directions, that is, there is no overlap on the same circle, which makes the laser energy uniform. By controlling the position (the distance between the second lens 4 and the first lens 3) of the second lens 4 on a Z axis only, the overlap 10 between one circle and another circle can be easily controlled, and therefore the purpose of making the laser scanning energy received on the entire wafer uniform is achieved more easily.

Referring to FIG. 1, in a further implementation of one embodiment, the mass transfer apparatus further includes a collimating lens 2 arranged on a laser path of the laser device 1, and configured to form a collimated beam by a divergent beam emitted from the laser device 1 and transmit the collimated beam to the first lens 3.

Referring to FIG. 2, in a further implementation of one embodiment, a release layer 61 is disposed on the first substrate 6, and the to-be-transferred Micro-LED chips 8 are disposed on the release layer 61 as an array. Furthermore, a second substrate 7 is arranged corresponding to the position of the first substrate 6. Specifically, the second substrate 7 covers the to-be-transferred Micro-LED chips 8; a bonding layer 71 is disposed on one surface, opposite to the release layer 61, of the second substrate 7. When the laser beam is emitted to the position of the to-be-transferred Micro-LED chips 8, the to-be-transferred Micro-LED chips 8 are separated from the release layer 61, and is adhered to the bonding layer 71. More specifically, the first substrate 6 and the second substrate 7 are both transparent substrates, so that the laser beam can pass through the first substrate 6.

In some implementations, the release layer 61 may be prepared from, for example, a fluorine coating, silicone resin, a water-soluble adhesive (for example, polyvinyl alcohol), polyimide, or the like. The laser beam may be selectively emitted to the release layer 61 at the position of the to-be-transferred Micro-LED chips 8 to allow the release layer 61 to be debonded or directly gasified, so that the to-be-transferred Micro-LED chips 8 are separated from the first substrate 6 and adhered to the bonding layer 71 of the second substrate 7, thereby achieving the purpose of transferring the to-be-transferred Micro-LED chips 8.

Referring to FIG. 1 and FIG. 4, in a further implementation of one embodiment, the circular light spot 9 is shaped as a circle, and the diameter of the circular light spot 9 is linearly increased or decreased along with changes of the distance between the first lens 3 and the second lens 4. Specifically, when the transmission assembly 5 drives the second lens 4 to move in a direction away from the first lens 3, the distance between the first lens 3 and the second lens 4 is increased, so that the diameter of the circular light spot 9 formed on the first substrate 6 by the laser beam transmitted through the first lens 3 and the second lens 4 from the laser device 1 is larger. Similarly, if the transmission assembly 5 drives the second lens 4 to move in a direction close to the first lens 3, the distance between the first lens 3 and the second lens 4 is decreased, so that the diameter of the circular light spot 9 formed on the first substrate 6 by the laser beam transmitted through the first lens 3 and the second lens 4 from the laser device 1 is smaller.

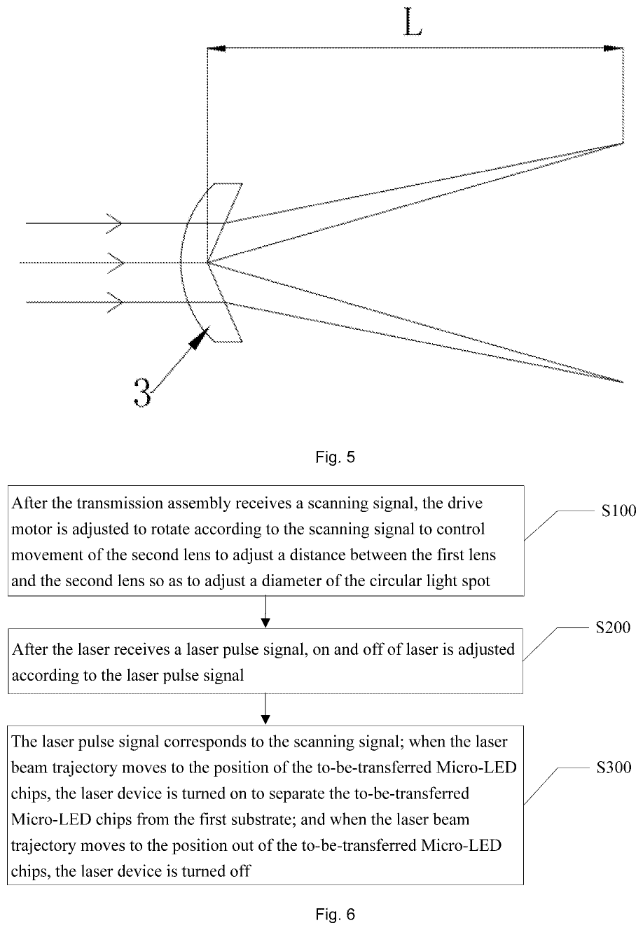

Furthermore, referring to FIG. 5, the distance between the first lens 3 and the second lens 4 is smaller than or equal to a focal length L of the first lens 3, that is, the maximum distance between the first lens 3 and the second lens 4 is equal to the focal length L of the first lens 3. Since the circular light spot is formed through the first lens 3, the diameter of the circular light spot is limited by the focal length of the first lens 3. When the distance between the first lens 3 and the second lens 4 reaches the focal length of the first lens 3, the diameter of the circular light spot 9 also reaches the maximum value.

Referring back to FIG. 1, in a further implementation of one embodiment, the laser device 1, the first lens 3, and the second lens 4 are coaxially arranged. Furthermore, the first lens 3 is an annular focusing lens including a focusing lens and a first conical lens. The first conical lens has a first cone angle α, and the laser beam is transmitted to the second lens 4 through the focusing lens and the first conical lens. Specifically, the focusing lens is composed of one or a plurality of spherical mirrors. Under cooperation of the focusing lens and the first conical lens, the laser beam can form a circular light spot through the first lens 3. It is understandable that the focusing lens may also be composed of one or a plurality of non-spherical mirrors, as long as the laser beam can form the circular light spot after passing through the first lens 3 under the cooperation between the focusing lens and the first conical lens. The second lens 4 is a second conical lens having a second cone angle _{R.} The second conical lens and the first conical lens are arranged in parallel, that is, the first lens 3 and the second lens 4 are coaxially arranged. The laser beam is transmitted through the first lens 3 that is composed of the focusing lens and the first conical lens, and then transmitted through the second conical lens, to form the circular light spot 9 at the position of the to-be-transferred Micro-LED chips 8. The diameter of the circular light spot 9 can be adjusted by adjusting a distance between the second conical lens and the first conical lens.

More specifically, the first cone angle a is equal to the second cone angle β, and both range from 45 degrees to 90 degrees. In some implementations, the first cone angle a and the second cone angle β may be set to 60 degrees.

Referring back to FIG. 1, in a further implementation of one embodiment, the transmission assembly 5 includes a drive motor 51, a screw 52, and a clamp 53. Specifically, the drive motor 51 is erected on one side of the first lens 3, the screw 52 is disposed on the drive motor 51, and the clamp 53 is disposed on the screw 52. The clamp 53 is connected to the second lens 4. The second lens 4 is connected to the clamp 53 along a direction perpendicular to the screw 52. During running of the drive motor 51, the drive motor 51 drives the screw 52 to rotate, the screw 52 drives the clamp to move front and back on the screw 52, so as to drive the second lens 4 to move front and back along a parallel direction of the screw 52 along with the clamp 53, thereby achieving the purpose of adjusting the distance between the second lens 4 and the first lens 3, and further achieving the purpose of changing the diameter of the circular light spot by controlling the distance between the first lens 3 and the second lens 4.

In a further implementation of one embodiment, the mass transfer apparatus further includes a controller respectively electrically connected to the laser device 1 and the drive motor 51. In a transfer process of the to-be-transferred Micro-LED chips 8, the controller sends a scanning signal, and the drive motor 51 receives the scanning signal and drives the second lens 4 to move front and back along the parallel direction of the screw 52, so as to adjust the diameter of the circular light spot. Moreover, the controller generates a laser pulse signal to the laser device 1 while generating the scanning signal. When a laser trajectory (a movement trajectory of the circular light spot) moves to the position of the to-be-transferred Micro-LED chips 8, the laser device 1 is triggered to be lighted, so that the to-be-transferred Micro-LED chips 8 corresponding to the circular light spot are separated from the first substrate 6.

Referring to FIG. 6, based on the same inventive concept, the present application further provides a mass transfer method. The method is applied to the mass transfer apparatus, including the following operations.

At S100, after the transmission assembly receives a scanning signal, the drive motor is adjusted to rotate according to the scanning signal to control movement of the second lens to adjust a distance between the first lens and the second lens so as to adjust a diameter of the circular light spot.

Specifically, the transmission assembly and the laser are both electrically connected to the controller; the controller generates a scanning signal to the transmission assembly; the transmission assembly controls movement of the second lens to control the distance between the first lens and the second lens so as to control the diameter of the circular light spot.

At S200, after the laser receives a laser pulse signal, on and off of laser is adjusted according to the laser pulse signal.

At S300, the laser pulse signal corresponds to the scanning signal; when the laser beam trajectory moves to the position of to-be-transferred Micro-LED chips, the laser device is turned on to separate the to-be-transferred Micro-LED chips from the first substrate; and when the laser beam trajectory moves to the position out of the to-be-transferred Micro-LED chips, the laser device is turned off.

Specifically, the controller generates a laser pulse signal to the laser while generating the scanning signal. When a laser trajectory (a movement trajectory of the circular light spot) moves to the position of the to-be-transferred Micro-LED chips, the laser device is triggered to be turned on, so that the to-be-transferred Micro-LED chips corresponding to the circular light spot are separated from the first substrate. When the laser trajectory moves to the position of the other Micro-LED chips that do not need to be transferred, the laser device is turned off, and the Micro-LED chips that do not need to be transferred are allowed to remain on the first substrate. Thus, the application may achieve selectively transferring of the Micro-LED chips on the first substrate.

In the foregoing mass transfer method, when the transmission assembly receives the scanning signal, the diameter of the circular light spot is adjusted as needed by controlling the distance between the first lens and the second lens; when the laser beam trajectory moves to the position of the to-be-transferred Micro-LED chips, the laser device is turned on to separate the to-be-transferred Micro-LED chips from the first substrate, thereby achieving the purpose of transferring the to-be-transferred Micro-LED chips to the second substrate from the first substrate.

In summary, the application provides the mass transfer apparatus and the mass transfer method. The apparatus includes: a laser device, a first lens, a second lens, and a transmission assembly. The laser device is configured to emit a laser beam; the first lens and the second lens are sequentially arranged on an emergent light path of the laser; the first lens is configured to shape the laser beam into a circular light spot through the first lens; and the second lens is configured to guide the circular light spot to a first substrate on which to-be-transferred Micro-LED chips are mounted. A transmission assembly is fixed on the second lens and configured to move the second lens to adjust a distance between the first lens and the second lens so as to adjust a diameter of the circular light spot. According to the application, the circular light spot is formed at the position of the to-be-transferred Micro-LED chips, and the distance between the first lens and the second lens is adjusted through the transmission assembly, so that the diameter of the circular light spot can be adjusted. Thus, a laser scanning mode in the application refers to a mode of scanning in the unit of circles and changing the scanning position by changing diameters of the circles. An overlapping mode of the scanning mode adopted in the application refers to an overlap between one circle and another circle. There is no overlap on the same circle, thereby making the laser energy more uniform. The overlap between the circles may be controlled by only controlling the distance between the first lens and the second lens, thereby precisely controlling the light spot trajectory to make the laser scanning energy on the overlap uniform. Therefore, according to the application, the laser scanning energy received on the entire wafer can be uniform, avoiding the problem that a large laser energy deviation between edge overlaps of the light spots may result in that a part of the overlaps have too much laser energy that may burn a separated object, and a part of the overlaps have too small laser energy or there is even no overlap so that the laser energy is too small to separate the object.

It is to be understood that applications of the application are not limited to the examples described above, those skilled in the art may make modifications or variations according to the foregoing description, and all these modifications and variations shall fall into the scope of protection of the application.

What claimed is:

1. A mass transfer apparatus, comprising a laser device, a first lens, a second lens, and a transmission assembly; wherein
the laser device is configured to emit a laser beam;
the first lens and the second lens are sequentially arranged on an emergent light path of the laser device;
the first lens is configured to shape the laser beam into a circular light spot;
the second lens is configured to guide the circular light spot to a first substrate on which to-be-transferred micro light-emitting diode chips are mounted; and
the transmission assembly is fixed on the second lens and the transmission assembly is configured to move the second lens to adjust a distance between the first lens and the second lens so as to adjust a diameter of the circular light spot.

2. The mass transfer apparatus according to claim 1, wherein the circular light spot is shaped as a circle, and the diameter of the circular light spot is linearly increased or decreased along with changes of the distance between the first lens and the second lens.

3. The mass transfer apparatus according to claim 2, wherein the distance between the first lens and the second lens is less than or equal to a focal length of the first lens.

4. The mass transfer apparatus according to claim 2, wherein the laser device, the first lens, and the second lens are coaxially arranged.

5. The mass transfer apparatus according to claim 4, wherein the first lens is an annular focusing lens, the annular focusing lens comprises a focusing lens and a first conical lens, the first conical lens has a first cone angle, and the laser beam is transmitted to the second lens through the focusing lens and the first conical lens.

6. The mass transfer apparatus according to claim 5, wherein the second lens is a second conical lens, the second conical lens has a second cone angle, and the laser beam is transmitted through the second conical lens to form the circular light spot at the position of the to-be-transferred micro light-emitting diode chips.

7. The mass transfer apparatus according to claim 6, wherein the first cone angle is equal to the second cone angle.

8. The mass transfer apparatus according to claim 7, wherein the first cone angle and the second cone angle both range from 45 degrees to 90 degrees.

9. The mass transfer apparatus according to claim 1, further comprising a collimating lens, the collimating lens is arranged on a laser path of the laser device, and the collimating lens is configured to form a divergent beam emitted from the laser device into a collimated beam and transmit the collimated beam to the first lens.

10. The mass transfer apparatus according to claim 1, wherein the transmission assembly comprises a drive motor, a screw disposed on the drive motor, and a clamp disposed on the screw;
the clamp is connected to the second lens; and during running of the drive motor, the second lens moves front and back along a parallel direction of the screw through the clamp.

11. The mass transfer apparatus according to claim 10, further comprising a controller, the controller is respectively electrically connected to the laser and the drive motor.

12. A mass transfer method, applied to the mass transfer apparatus according to claim 1, comprising:
after the transmission assembly receives a scanning signal, adjusting the drive motor to rotate according to the scanning signal to control movement of the second lens to adjust a distance between the first lens and the second lens so as to adjust a diameter of the circular light spot;
after the laser device receives a laser pulse signal, adjusting on and off of laser according to the laser pulse signal;
wherein the laser pulse signal corresponds to the scanning signal; when a laser beam trajectory moves to the position of to-be-transferred micro light-emitting diode chips, turning on the laser device to separate the to-be-transferred micro light-emitting diode chips from the first substrate; and when the laser beam trajectory moves to the position out of the to-be-transferred micro light-emitting diode chips, turning off the laser device.

13. The mass transfer apparatus according to claim 1, wherein a release layer is disposed on the first substrate, and the to-be-transferred micro light-emitting diode chips are disposed on the release layer as an array.

14. The mass transfer apparatus according to claim 13, further comprising a second substrate, the second substrate covers the to-be-transferred micro light-emitting diode chips, and a bonding layer is disposed on one surface, opposite to the release layer, of the second substrate.

15. The mass transfer apparatus according to claim 7, wherein the first cone angle and the second cone angle both are 60 degrees.

16. The mass transfer apparatus according to claim 11, wherein the controller is configured to send a scanning signal, the drive motor is configured to receive the scanning signal and drive the second lens to move front and back along the parallel direction of the screw, so as to adjust the diameter of the circular light spot.

17. A mass transfer method, applied to the mass transfer apparatus according to claim 2, comprising the operations:
after the transmission assembly receives a scanning signal, adjusting the drive motor to rotate according to the scanning signal to control movement of the second lens to adjust a distance between the first lens and the second lens so as to adjust a diameter of the circular light spot;
after the laser device receives a laser pulse signal, adjusting on and off of laser according to the laser pulse signal;
wherein the laser pulse signal corresponds to the scanning signal; when a laser beam trajectory moves to the position of to-be-transferred micro light-emitting diode chips, turning on the laser device to separate the to-be-transferred micro light-emitting diode chips from the first substrate; and when the laser beam trajectory moves to the position out of the to-be-transferred micro light-emitting diode chips, turning off the laser device.

18. A mass transfer method, applied to the mass transfer apparatus according to claim 3, comprising:
after the transmission assembly receives a scanning signal, adjusting the drive motor to rotate according to the scanning signal to control movement of the second lens to adjust a distance between the first lens and the second lens so as to adjust a diameter of the circular light spot;
after the laser device receives a laser pulse signal, adjusting on and off of laser according to the laser pulse signal;
wherein the laser pulse signal corresponds to the scanning signal; when a laser beam trajectory moves to the position of to-be-transferred micro light-emitting diode chips, turning on the laser device to separate the to-be-transferred micro light-emitting diode chips from the first substrate; and when the laser beam trajectory moves to the position out of the to-be-transferred micro light-emitting diode chips, turning off the laser device.

19. A mass transfer method, applied to the mass transfer apparatus according to claim 4, comprising:
after the transmission assembly receives a scanning signal, adjusting the drive motor to rotate according to the scanning signal to control movement of the second lens to adjust a distance between the first lens and the second lens so as to adjust a diameter of the circular light spot;
after the laser device receives a laser pulse signal, adjusting on and off of laser according to the laser pulse signal;
wherein the laser pulse signal corresponds to the scanning signal; when a laser beam trajectory moves to the position of to-be-transferred micro light-emitting diode chips, turning on the laser device to separate the to-be-transferred micro light-emitting diode chips from the first substrate; and when the laser beam trajectory moves to the position out of the to-be-transferred micro light-emitting diode chips, turning off the laser device.

20. A mass transfer method, applied to the mass transfer apparatus according to claim 5, comprising:
after the transmission assembly receives a scanning signal, adjusting the drive motor to rotate according to the scanning signal to control movement of the second lens to adjust a distance between the first lens and the second lens so as to adjust a diameter of the circular light spot;
after the laser device receives a laser pulse signal, adjusting on and off of laser according to the laser pulse signal;
wherein the laser pulse signal corresponds to the scanning signal; when a laser beam trajectory moves to the position of to-be-transferred micro light-emitting diode chips, turning on the laser device to separate the to-be-transferred micro light-emitting diode chips from the first substrate; and when the laser beam trajectory moves to the position out of the to-be-transferred micro light-emitting diode chips, turning off the laser device.
